(19) United States
(12) Patent Application Publication
(10) Pub. No.: US 2012/0222614 A1
(43) Pub. Date: Sep. 6, 2012

(54) SELF-CLOSING EMBEDDED SLIT VALVE

(76) Inventors: Dongliang Daniel SHEU, Hsinchu (TW); Chun-Ting Hou, Zhunan Township (TW)

(21) Appl. No.: 13/177,073

(22) Filed: Jul. 6, 2011

(30) Foreign Application Priority Data
Mar. 3, 2011 (TW) 100107145

(51) Int. Cl. F16K 31/02; H01L 21/00; C23C 16/455

(52) U.S. Cl. 118/715; 251/129.15

(57) ABSTRACT

A slit valve module includes two solenoid valves and a cover plate with magnetic material or magnetically attractable material, one of the solenoid valves is positioned above or under the plate and another one of the solenoid valves is positioned at a side of the plate. These two solenoid valves can respectively generate horizontally and vertically magnetic forces, thereby facilitating operate of the plate. When the slit valve is closed, the slit valve can employ the weight of the plate to fall down. Moreover, when the plate approaches the vacuum chamber, the pressure difference can draw the plate. Therefore, the existing gravity and vacuum resources can be taken advantage of to use minimum magnetic energy to control the slit valve effectively and efficiently.

### FIELD OF THE INVENTION

The present invention generally relates to a slit valve, in particular, to a self-closing embedded slit valve with simplified structure, used in semiconductor equipment.

### DESCRIPTION OF THE PRIOR ART

In the semiconductor manufacturing process, it has to maintain enough vacuum in the process chamber for preventing the wafer from being polluted. Thus, a slit valve is required to be configured between the process chamber and the transfer module. When the entrance is closed by the slit valve, it can facilitate the vacuum source to suck air from the process chamber, thereby enabling the subsequent manufacturing processes. Besides, in order to keep the vacuum in the process chamber, a vacuum pump can be introduced to keep sucking air during the process. Aforementioned slit valve can be widely applied in various processing equipment such as chemical vapor deposition (CVD) and physical vapor deposition (PVD) processes when processing a wafer or a glass substrate of a LCD panel.

One example of conventional slit valves can be referred to FIG. 1. It includes 18 components/sub-assemblies, and is an independent module connected external to the process chamber driven by mechanical forces. Because it consists of many components, the possibility of malfunction is consequently high.

Another example of conventional slit valves can be referred to FIG. 2, which shows U.S. patent publication number 2008/0083897 A1, and the operation method can be referred to FIG. 3. As shown, the slit valve is also an independent module connected externally to the process chamber and driven by mechanical forces.

Another example can further be referred to FIG. 4, which shows U.S. patent publication number 2008/0083897 A1. In this patent publication, the slit valve is operated in 45 degrees perpendicular to the entrance of the chamber wall. Although the friction between the slit valve module and the O-ring surrounding the entrance may be avoided, it is still an independent module connected externally to the process chamber and driven by mechanical forces.

In semiconductor processes, such as CVD or PVD, the common location of the slit valve can be seen in FIG. 5 wherein plural cassettes 102s are used to load the wafer into the transfer module 103 or unload the wafer out of the transfer module 103. A Plurality of process chambers 101 are connected to the transfer module 103 via corresponding slit valve 104. In other words, the slit valves 104 are connected externally to the process chambers 101, and further connected to the transfer module 103. Note that it is commonly needed that chamber must be kept in vacuum to perform wafer manufacturing processing. Therefore, the vacuum “resource” is already introduced for manufacturing processes during the valve closed period.

Traditional slit valve is generally composed of a body with mechanical mechanism, including a cylinder for driving the gate. Taking the cylinder-type slit valve for example, the body is situated on top of the chamber wall as indicated in FIGS. 5a & 5b. A sliding guide assembly, a connecting lever, and a plate respectively are connected to each other. Typically, an O-ring is mounted on the peripheral of the gate opening to ensure sealing. The piston rods of the sliding guide assembly and the cylinder are connected to each other. When closing the entrance by the slit valve, the sliding guide assembly may be pushed down by the piston rod of the cylinder, thereby pushing the cover plate down to close the valve and then sideward to seal the opening.

In a Taiwanese semiconductor fab, it was found that one of the protrusions of the sliding guide assembly, as indicated as 201 in FIG. 6a, was broken due to stress concentration and material fatigue causing uneven valve closing which in turn rub out O-ring particles during valve closing. The rubbed-out O-ring particles were drawn into the manufacturing chambers depositing on the wafers causing wafer defects and scraps.

In order to solve the aforementioned problem, a pair of long pins (202) in the FIG. 6B were introduced to replace the protrusions 201 in FIG. 6a hoping to ease the stress concentration at the corner of 201. However, that worked just temporarily. The same fatigue and stress concentration factors will come back again after many repeated open-close cycles of the slit valve. That is, even though the usage duration of the slit valve can be prolonged, the potential risk of the wafer's defects derived from the rubbed-off O-ring particles will still happen in the future. Further, the operation of the slit valve by mechanical means takes much time and energy. Instead, this invention solved the afore mentioned failure mode permanently by trimming the slit valve part count from the original 18 to 3, using electromagnetism and existing gravity and pressure differential resources to operate an internal valve instead of the traditional huge external mechanism to drive the valve. Because this invention is able to take advantage of existing gravity and pressure differential to maintain the valve closing the energy needed to maintain the valve closing during wafer processing is saved which constitute approximate 90% of the valve operational times.

### SUMMARY OF THE INVENTION

The present invention provides a self-closing embedded slit valve, so as to overcome aforementioned difficulties and shortcomings.

One purpose of the present invention is to avert the wafer's defect issue caused by abraded O-ring. Because the two orthogonal movements (Closing & Tightening) of slit valve of the present invention are driven separately by electromagnetic and gravity means separately, the coupled uneven movement of the cover plate against the O-ring can be avoided thus designed-out the particle rubbing problem and the original failure mode caused by the protrusion breakage at 201 in FIG. 6a.

Instead of the conventional slit valve opening/closing mechanism, the current invention gets rid of all external mechanical control and driving mechanisms as indicated in FIG. 1. Instead, as shown in FIG. 7, the current invention retains only the cover plate of the slit valve and places it inside the chamber wall of the slit valve. The valve opening is achieved by first attracting or pushing the 301 cover plate/block vertically away from the O-ring by a pulse of the electromagnet 303 on the side of the chamber wall. Then, applying the electronic magnet (302 solid valve) to attract the cover block/plate up to a position where the opening 304 of the cover block/plate aligns with the opening slit on the chamber effectively opening the slit valve for the robot arm to pass through so that the transfer of wafer between the chamber and the transfer mechanism can be achieved. To close and tighten the valve, a short pulse is applied on the side electromagnet/solenoid to make sure that the cover bock is attracted or pushed away from the O-ring and the top magnetism is dropped so that the cover block can be dropped down by gravity to the lower position effectively closing the valve. Then, either a short pulse of side solenoid can push the cover block to seal the valve against the O-ring or the pressure differential between the vacuum in the process chamber and the normal pressure in the transfer mechanism can seal the valve. The existing pressure differential generated by the vacuum process in the manufacturing chamber can keep the valve is good sealing for all the time when the wafer is in manufacturing process without needing to use extra energy to maintain its sealed position. Note that in normal operation, approximately 90% of the chamber operating time, the valve is closed to process the wafer. That mean the current invention is able to take advantage of the existing gravity and pressure differential between the chamber and the transfer module to maintain the valve position without using any energy. That is, only during the valve opening time, which constitute only about 10% of the whole operational cycle time, the current invention need to use energy. On the contrast, all existing external mechanically driven valve will need electrical and/or pneumatic energy to drive and maintain the valve position at all times. Furthermore, the existing external mechanically driven valve weights about 6 kilograms for all the 18 moving components/sub-assemblies while the moving block of the present invention weights only about 0.6 kilogram. Therefore, a 10% of time needing energy and 10% of part weight needing to be moved, a rough estimate will indicate that the present invention will need only 10%×10%=1% of the existing energy level for operations. FIG. 15 indicates the benefits of the present invention in component count, system part costs, and energy savings. Compared to the prior art of the existing solution, the present invention can reduce 83.3% of part count, 95.6% of part costs if the slit valve is build anew, and approximately 99% of operational energy. Furthermore, it is possible to further reduce the cover block weight by introducing “void” into the cover block as indicated in FIG. 9.

Based on aforementioned description, the present invention utilizes magnetic force, gravity, and pressure difference derived from vacuum to control the slit valve, and theses forces can be easily controlled independently and vertically thus avoiding the uneven movement of existing cover plate to rub the O-ring particles. Therefore, the original failure mode is permanently designed-out.

Aforementioned description is to illustrate purposes of the present invention, technical characteristics to achieve the purposes, and the advantages brought from the technical characteristics, and so on. And the present invention can be further understood by the following description of the preferred embodiment accompanying with the claims.

### BRIEF DESCRIPTION OF THE DRAWINGS

FIG. 1 shows a conventional slit valve;

FIG. 2 shows another conventional slit valve;

FIG. 3 shows the operation method of another conventional slit valve;

FIG. 4 shows the other conventional slit valve;

FIG. 5a shows a traditional semiconductor apparatus with slit valves;

FIG. 5b shows a traditional semiconductor apparatus of FIG. 5a.

FIG. 6a shows a traditional sliding guide assembly;

FIG. 6b shows an improved traditional sliding guide assembly;

FIG. 7a and FIG. 7B show a preferred embodiment of the slit valve module of the present invention;

FIG. 8 shows front view of the preferred embodiment of the slit valve module;

FIG. 9a and FIG. 9B show the inner structure of the plate;

FIG. 10a and FIG. 10B show another embodiment of the slit valve module of the present invention;

FIG. 11 shows the plate of another embodiment of the slit valve module;

FIG. 12 shows a table categorizing various types of the plate of the present invention;

FIG. 13 shows the method of closing the slit valve of the present invention;

FIG. 14 shows the method of opening the slit valve of the present invention;

FIG. 15 shows the beneficial table comparing the present invention and the prior art.

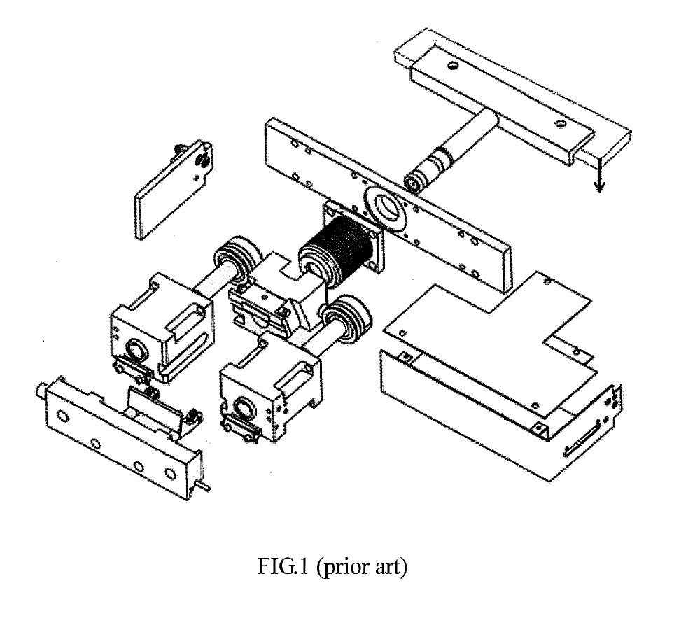

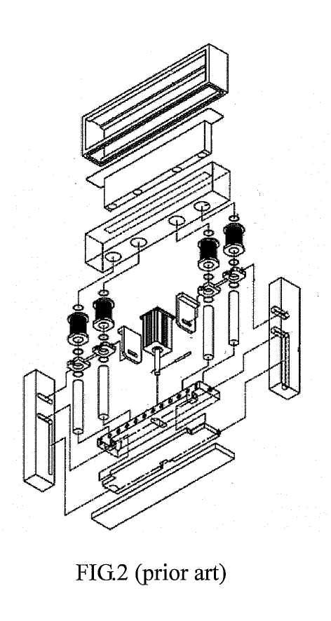

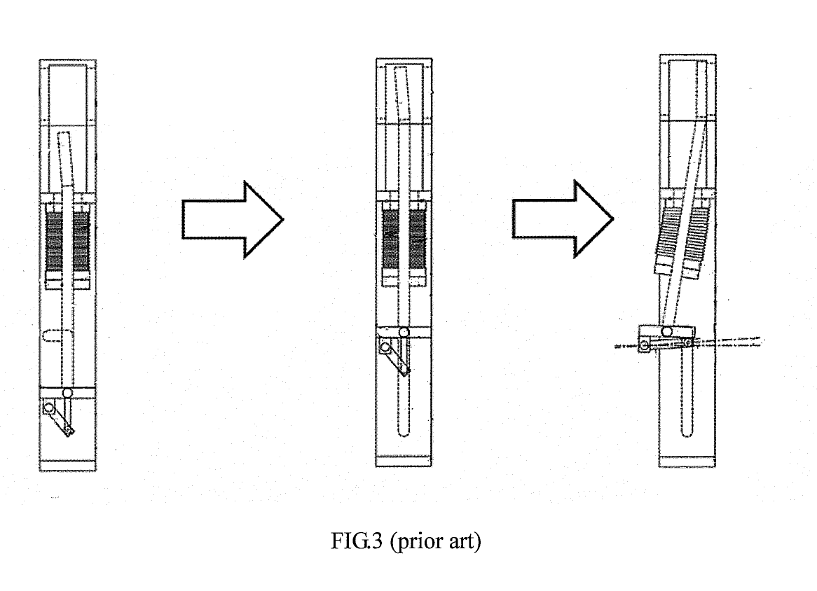

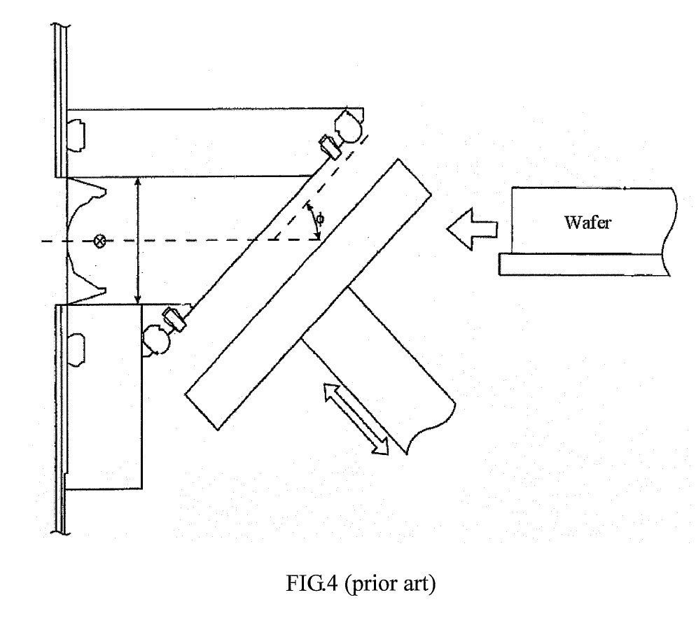

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims.

The main technical feature is to employ two solenoid valves and a hollow plate with magnetic material as a slit valve module, wherein a solenoid valve is configured above the plate, and another solenoid valve is set on a side of the plate in the chamber wall. These solenoid valves can respectively generate vertical and horizontal magnetic force when the power is on, so as to drive the plate to move. When the slit valve is closed, the present invention make the plate fall down by utilizing the weight of the plate itself without needing to apply any energy during the valve closing/closed period. Further, when the plate approaches the vacuum chamber, the existing pressure difference between the vacuum chamber and the environment can be also employed to maintain the plate in sealed position without needing any external energy. Therefore, the plate just needs to be held by the solenoid valve when the slit valve is opened or in the “open” position. This is the concept of using existing (gravity and pressure differential) resources to operate the valve 90% of the time. The slit valve disclosed by the present invention can be widely applied on any mechanism or apparatus which requires a slit valve, but is not limited in the semiconductor process such as CVD or PVD, etc.

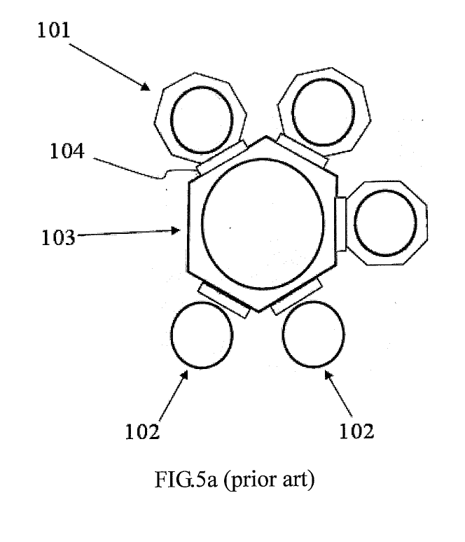

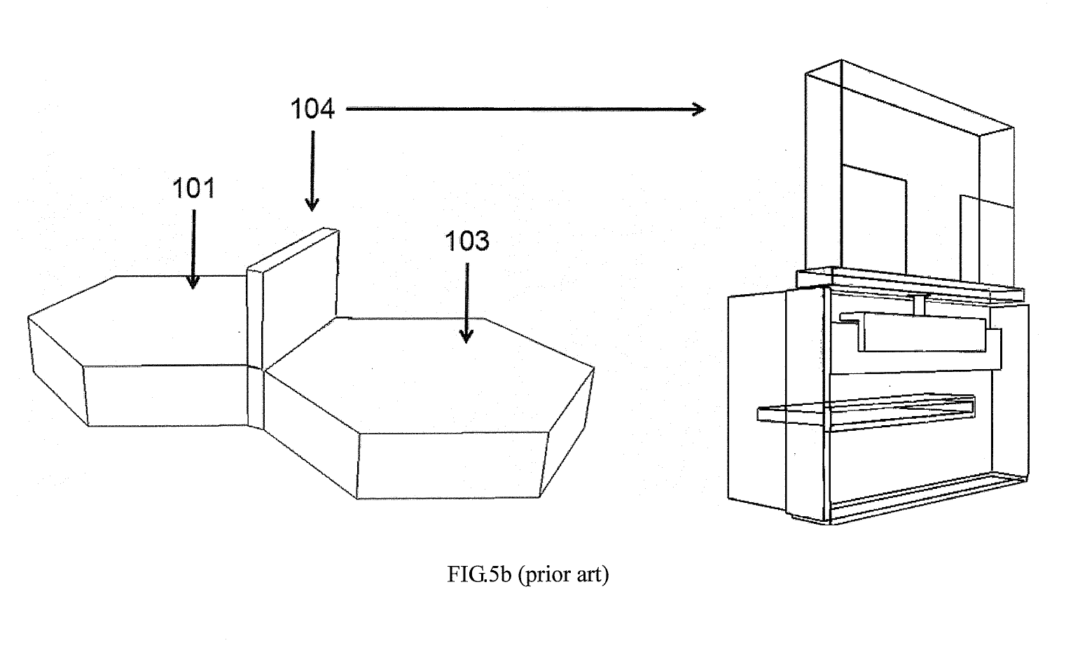

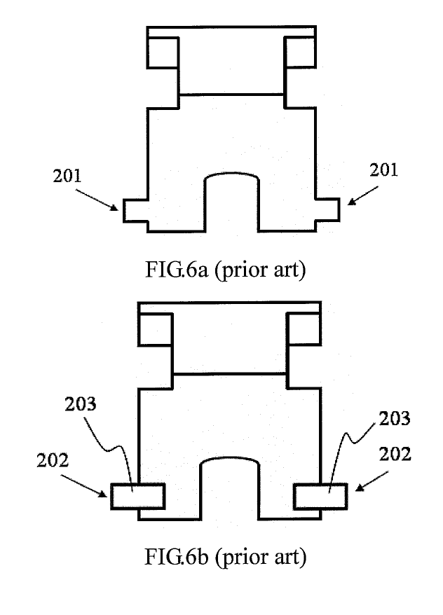

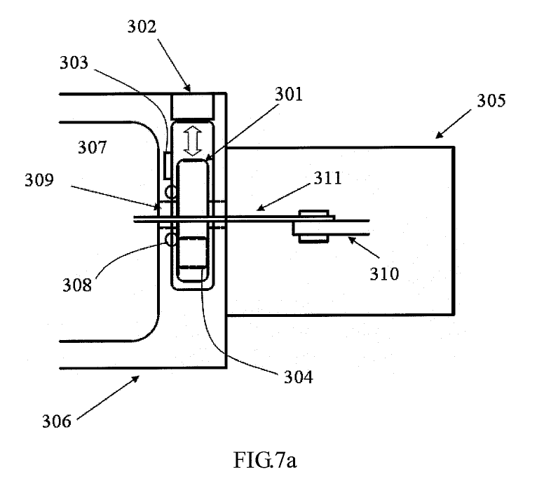

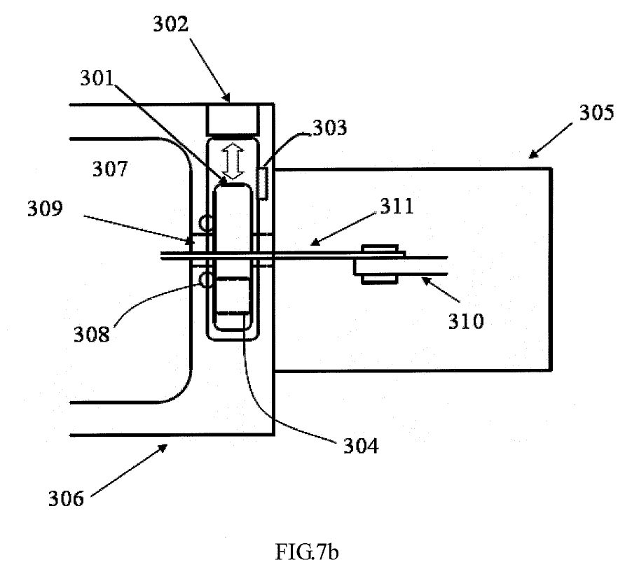

The cross-sectional diagram of FIG. 7 shows a preferred embodiment of the slit valve module and the applied semiconductor apparatus. This apparatus includes a plate 301, a first solenoid valve 302, a second semiconductor 303, a slot 304, a transfer module 305, a process chamber 306, a vacuum chamber 307, an O-ring 308, a channel 309, a mechanical arm 310 and a loading device 311. The loading device 311 is connected to the mechanical arm 310, for example, the loading device 311 can be pivotally connected to the mechanical arm 310, and it is used to load or carry the work piece (ex: a wafer). The mechanical arm 310 is introduced for controlling the loading device 311 to load or unload the work piece. The slit valve module composed of the plate 301, the first solenoid valve 302, and the second solenoid valve 303 is embedded in the wall of the process chamber 306. This is contrasted to the conventional slit valve, which is connected between the transfer module 305 and the process chamber 306 with externally attached driving mechanism as indicated in FIG. 5B. The process chamber 306 further comprises a vacuum chamber 307 where can be vacuumized by a vacuum source, so as to act as the process environment. The dash line depicted in the process chamber 306 means the channel 309, which runs through the inner wall where the plate 301 locates. Specifically, one end of the channel 309 is connected to the vacuum chamber 307, and another end is connected to the transfer module 305. In this case, when the slit valve module is opened, namely, the slot 304 is overlapped by the channel 309, a penetrated path can be formed, so as to provide the loading device moved in or out. In the embodiment, an O-ring 308, formed by elastic material such as rubber, can be configured around the channel 309. When the slit valve module is closed, the plate 301 can be attached to the O-ring 308, so as to prevent the plate 301 from colliding with the inner wall of the process chamber 306.

A shown in this figure, the plate 301 is embedded in the inner wall of the process chamber 306. Specifically speaking, the inner wall of the process chamber 306 can be digged to form a space, so as to contain the plate 301. The height of the space is preferably higher than the plate 301 for providing the plate 301 to move vertically, thereby facilitating to open or seal the channel 309. The dash line depicted on the plate 301 illustrates the slot 304. When the slit valve module is opened, namely, the plate 301 is attached to the first solenoid valve 302, the slot 304 and the channel 309 can overlap, so that the loading device 311 moves inward or outward, thereby facilitating to load or unload the work piece. Besides, the plate 301 further comprises magnetic material for providing the first solenoid valve 302 and the second solenoid valve 303 to attract or repulse it. In some embodiments, the plate 301 can be hollow for reducing the weight and saving the cost. Further, the hollow plate 301 can also reduce the magnetic force required for attracting the plate 301 to move upwards, thereby achieving the effect of energy-saving.

The first solenoid valve 302, which is correspondingly configured above the plate 301 and embedded in the inner wall of the process chamber 306, can be coupled to the power source for receiving electric and converting to magnetic energy. Any person skilled in the art should understand the means for coupling the solenoid valve to the power source, and therefore, in order to simplify the figure, the power source is not shown. When the magnetic orientation of the first solenoid valve 302 is the same as the plate 301, the repulsion force can be generate, so as to push the plate to leave the first solenoid valve 302 vertically. Contrarily, when the magnetic orientation of the first solenoid valve is opposite to the plate 301, attractive force can be generated, so as to attract the plate 301 to approach the first solenoid valve 302. Thus, the first solenoid valve 302 can be introduced to control the vertical motion of the plate 301, and the magnetic orientation can be controlled by the voltage outputted from the power source. For instance, when the power source outputs positive electrical potential the first solenoid valve 302 can act as N pole; when the power source outputs negative electrical potential, the first solenoid valve 302 acts as S pole. Aforementioned relation between the electrical potential and the magnetic orientation is only an example used for explaining the present invention instead of limiting the present invention, and other similar examples should also be covered in the present invention. Similarly, in other embodiments, the first solenoid valve 302 can also be correspondingly configured under the plate 301.

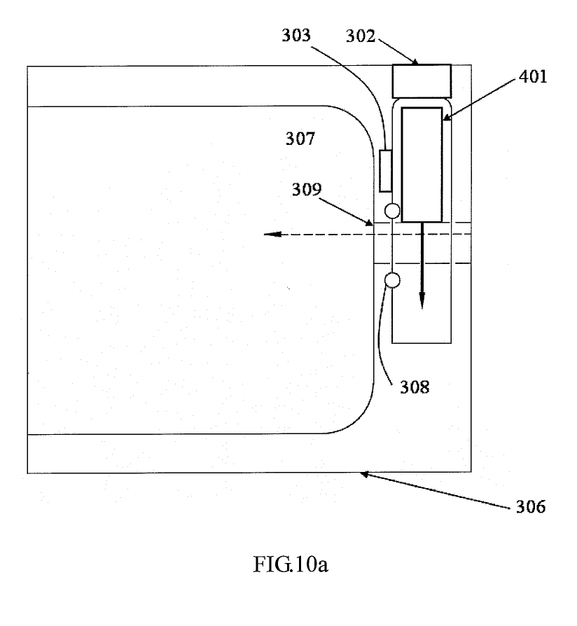

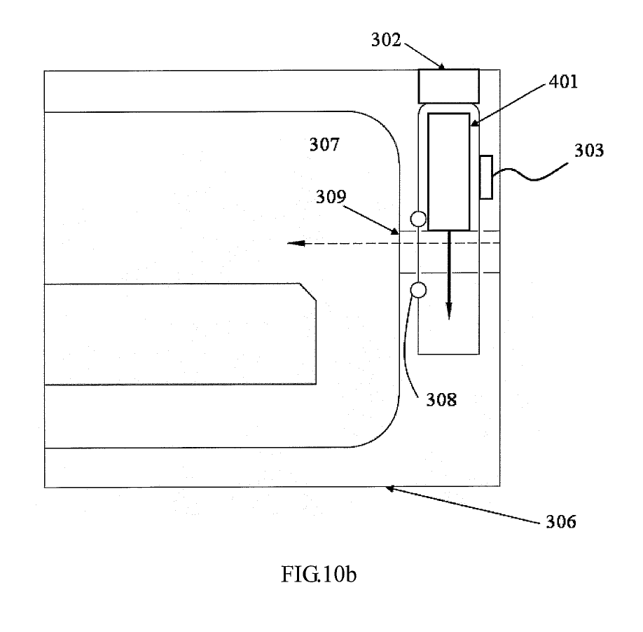

The second solenoid valve 303 is correspondingly configured at side by the plate 301 and embedded in the wall of the process chamber 306. Similar to the first solenoid valve 302, the second solenoid valve 303 can also coupled to the power source for receiving electric energy and converting to magnetic energy. When the magnetic orientation of the second solenoid valve 303 is the same as the magnetic material of the plate 301, the repulsion force can be generated, so as to push the plate 301 to leave the second solenoid valve 303 horizontally; Contrarily, the 303 solenoid valve can also be situated on the opposite side of the plate in FIG. 10 when the magnetic orientation of the second solenoid valve 303 is opposite to that of the plate 301 to use attractive force instead of repulsion force for the same purpose. Accordingly, the second solenoid magnetic 303 can be used to control the horizontal motion of the plate 301 from either side of the cover plate/block. The magnetic orientation can be controlled by the electrical potential outputted from the power source. By the same reasoning, the 302 solenoid valve can also be situated at the bottom side of the cover plate instead of the top side if repulsion force can be used instead of attraction force. For example, when the power source outputs positive electrical potential, the second solenoid valve 303 can act as N pole; when the power source outputs negative electrical potential, the second solenoid valve 303 acts as S pole. Aforementioned relation between the voltage and the magnetic orientation is only an example used for explaining instead of limiting the present invention, and other similar examples should also be covered in the present invention.

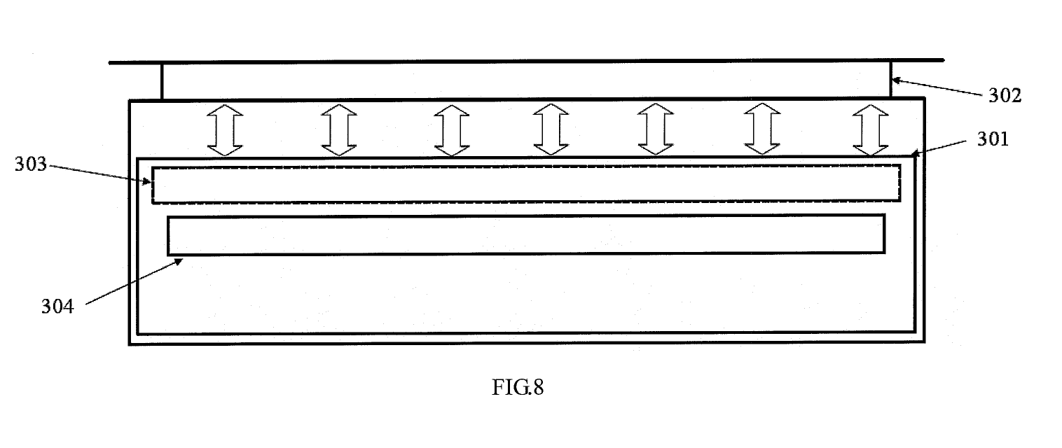

Referred to FIG. 8, this figure shows the front view of the slit valve module disclosed by the present invention for providing another viewing angle for readers, so as to make readers understand the present invention more clearly. Arrows in this figure represent the moving direction of the plate 301 when power is provided for the first solenoid valve 302. When the magnetic orientation of the plate 301 is opposite to the first solenoid valve 302, the plate 301 and the first solenoid valve 302 may attract each other, so that the plate 301 can be attracted upwards and attached to the first solenoid valve 302. In the mean time, the slot 304 can be overlapped on the channel 309 (not shown in the figure) for providing the loading device 311 (not shown in the figure) moved in or out.

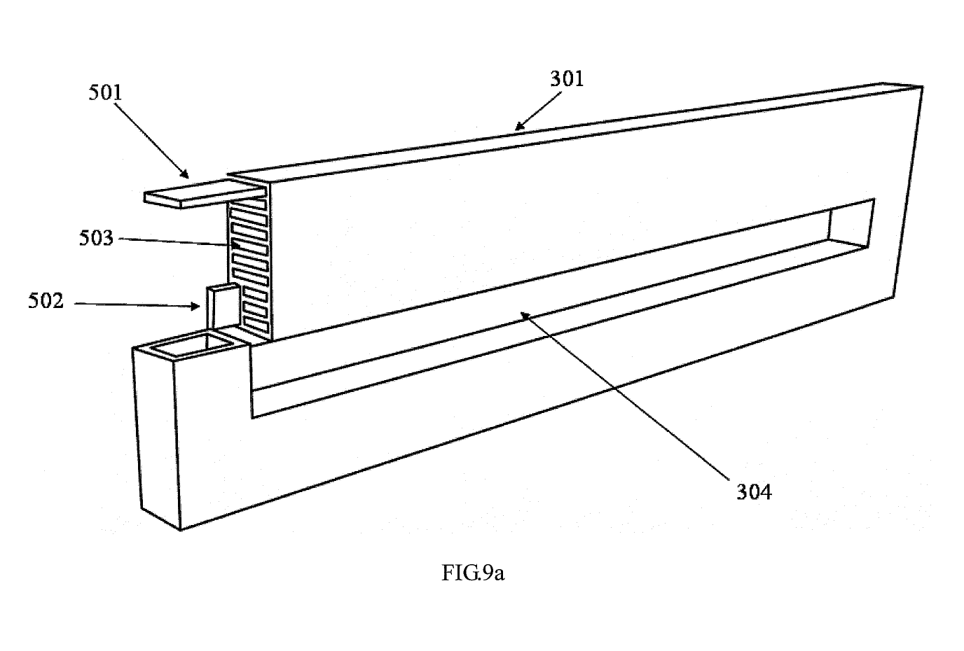

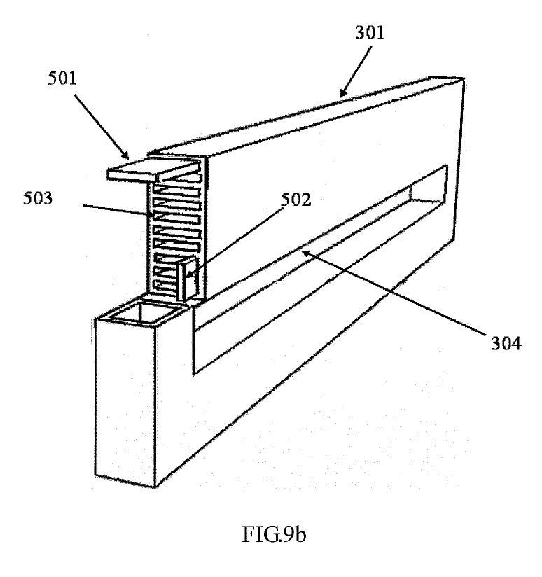

FIG. 9 shows the inner configuration of another possible embodiment of the cover block/plate. As shown, the plate 301 contains a first magnetic element 501, a second magnetic element 502, a slot 304, and a plurality of cavities 503. In some embodiments, the first magnetic element 501, configured in one cavity 503, is a magnet, wherein the main surface which covers most area faces upwards and parallels with the first solenoid valve 302 (not shown in this figure), so as to facilitate the magnetic performance. In some embodiments, the second magnetic element 502, configured in a cavity 503, is a magnet, wherein the main surface, covering most area, faces laterally and parallels with the second solenoid valve 303 (not shown in the figure), so as to facilitate the magnetic performance. Those cavities 503 can also be employed to reduce the burden of the plate 311 in addition to containing the first magnetic element 501 and the second magnetic element 502, so that the cost can be further reduced.

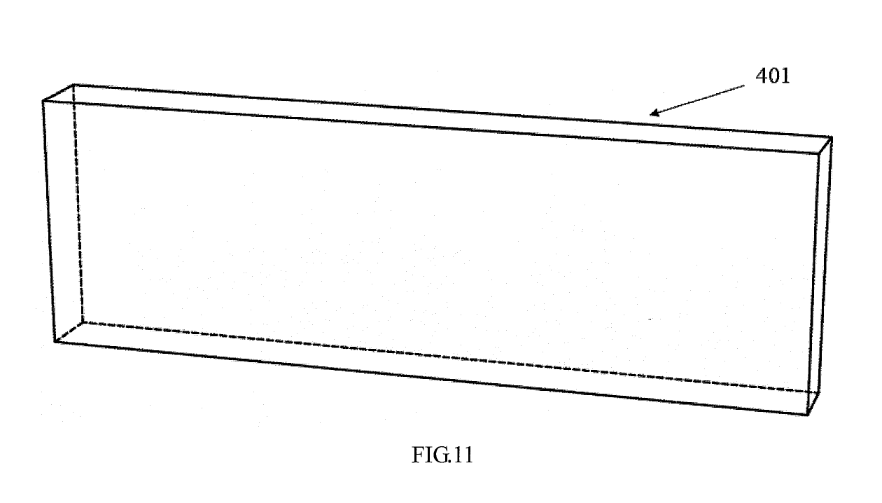

Referred to FIG. 10, this figure shows another embodiment of the present invention, wherein the plate 401 is different from aforementioned embodiments, and FIG. 11 can also be incorporated to be referred herein. As shown in FIG. 11, the plate 401 is a block without any slot, and the height of the embodiment is lower than the one of aforementioned embodiments. In this case, when the plate 401 is attached to the first solenoid valve 302, no obstacle can be found in the channel 309, so that the loading device 311 (not shown in this figure) can be free to move in or out, thereby achieving the purpose of opening the slit valve. When the plate 401 is not attached to the first solenoid valve 302, it can fall down due to the gravity, whereby blockading the channel 309 and subsequently achieving the purpose of sealing the slit valve.

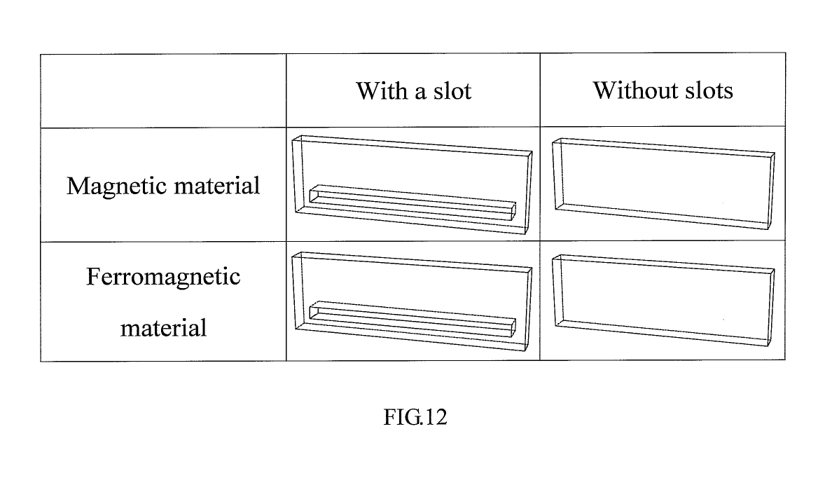

Besides, referred to FIG. 12, this figure shows a table categorizing various types of the plate of the present invention. As shown in the table, the types of the plate are mainly dependent on two different parameters, one is whether a slot is included or not, another is the material of the plate. Specifically speaking, the material can be classified in magnetic material and ferromagnetic material. For example, the magnetic material may actively attract others via magnetic force, such as the magnet. The ferromagnetic material which may include ordinary metal, such as iron, stainless steel, etc, cannot actively attract others by magnetic force, but can be attracted by the magnetic material. By these parameters, four different plates can be introduced, they include: a plate with a slot and formed by the magnetic material, a plate formed by the magnetic material without any slot, a plate with a slot and formed by the ferromagnetic material, and a plate formed by the ferromagnetic material without any slot.

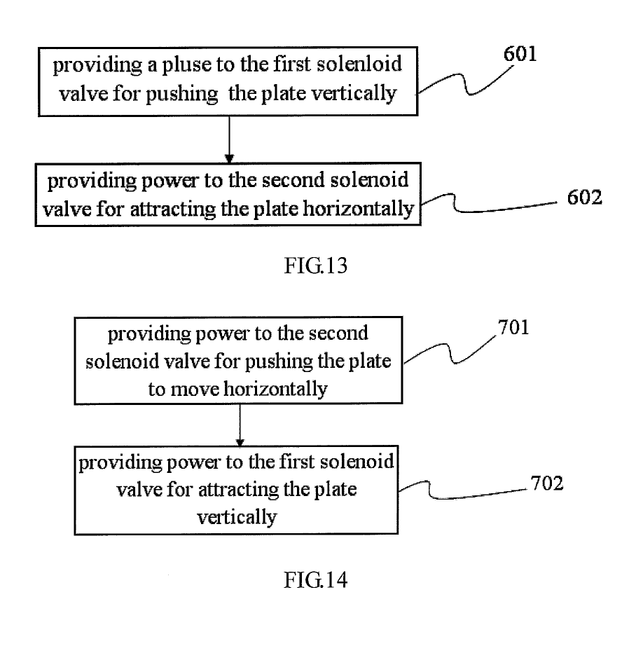

Referred to FIG. 13, the figure shows the method of sealing the slit valve of the present invention, and the steps are described in the following. At First, in the step 601, a pulse is provided for the first solenoid valve by a power source, whereby pushing the plate to vertically move downwards. In particular, only one pulse for the first solenoid valve is required for generating instantaneous repulsion force to push the plate. After the plate is pushed, it can naturally fall down due to the weight of the plate itself without providing continuous magnetic repulsion force. Hence, the first solenoid can be power-off after the plate is pushed downwardly, thereby achieving the purpose of saving energy. Subsequently, in the step 602, the power is provided to the second solenoid valve by the power source for attracting the plate to move horizontally, thereby sealing the channel of the process chamber. In the mean time, the plate can be attached to the O-ring around the channel, and the slot of the plate and the channel of the vacuum chamber are not overlapped, so as to facilitate the closure of the vacuum chamber. Furthermore, the plate can be attached to the O-ring much more tightly by the pressure difference between the vacuum chamber and the environment when the plate approaches the vacuum chamber since the vacuum chamber is vacuumized. Based on the foregoing, the present invention just needs instantaneous magnetic force when sealing the slit valve, and the energy for rest steps can be provided by the gravity and the vacuum force.

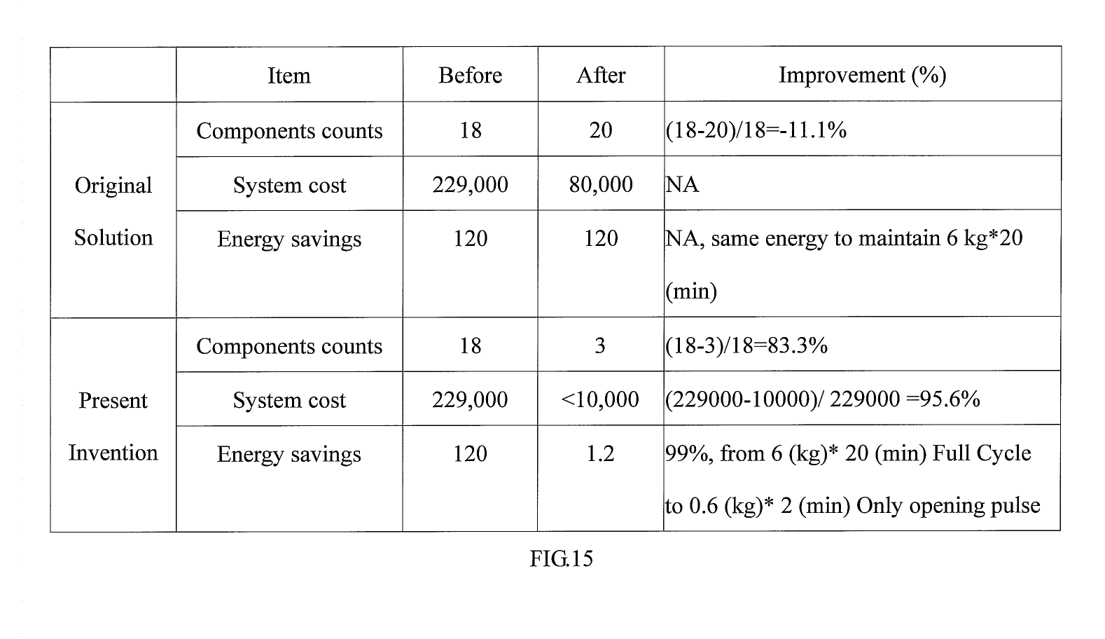

Referred to FIG. 14, the figure shows the method of opening the slit valve of the present invention, and the steps are described as follows. At first, in the step 701, a pulse is provided to the second solenoid valve by the power source for generating repulsive magnetic force to push the plate to leave the O-ring around the channel. In this step, the voltage provided by the power source should be reversed to the method of closing the slit valve shown in FIG. 13, so as to provide opposite magnetic orientation and push the plate via the repulsion force. And then, in the step 702, power is provided to the first solenoid valve by the power source, whereby attracting the plate to move upwardly and attached to the first solenoid valve, so that the slot of the plate overlaps the channel of the process chamber, thereby forming a penetrated path for facilitating the loading device moves in or out. Similarly, on the method of opening the slit valve, the voltage received by the first solenoid valve should be reversed to which of the method of closing the slit valve, so as to provide opposite magnetic orientation, thereby attracting the plate to move and attached to the first solenoid valve via the attractively magnetic force.

Based on aforementioned method of opening and closing the slit valve, the solenoid valve just requires to work in the less time that the slit valve opens for attracting the plate, and in the rest of the time, the gravity and the pressure difference between the vacuum chamber and the environment can be employed to close the slit valve or to keep the slit valve closed. Nevertheless, in the prior art, external energy is required no matter when the slit valve is the open or closes state. In practice, the great majority of the time, the slit valve is in the close state to process wafers. Therefore, the present invention can save a large amount of energy. That is, in the great majority of times there is no need of external energy to operate the valve. The existing gravity and pressure differential between the inside and outside of the chamber are used to operate the valve. This is “in addition to” the fact that the existing mechanical mechanism of the valve operation consumes much more energy than the electro-magnetic system used in this invention.

In aforementioned embodiments, the slit valve is designed to remain closed in most time and opened in less time. However, if the practice is to have the slit valve open in most time and close the slit valve in less time, the aforementioned embodiments can also be modified to take advantage of the existing gravity and pressure differential for valve opening instead of closing and the same energy-saving purpose can be achieved easily. For example, referred to FIG. 7, the channel 309 of the process chamber can be configured under the original position, so that the slot 304 can overlap the channel 309 to form a path when the plate 301 is not attached to the first solenoid valve 30, thereby opening the slit valve. In this case, the first solenoid valve 302 just needs to provide magnetic force to attract the plate 301 when keeping the slit valve closed in less time, and in the rest time, the plate 301 can keep identical position to open the slit valve or keep the slit valve opened owning to the weight of the plate itself, thereby reducing energy consumption.

The foregoing preferred embodiment of the present invention is illustrative of the present invention rather than limiting the present invention. Having described the invention in connection with a preferred embodiment, modification will now suggest itself to those skilled in the art. Thus, the invention is not to be limited to this embodiment, but rather the invention is intended to cover various modifications and similar arrangements included within the spirit and scope of the appended claims, the scope of which should be accorded the broadest interpretation so as to encompass all such modifications and similar structures. While the preferred embodiment of the invention has been illustrated and described, it will be appreciated that various changes can be made therein without departing from the spirit and scope of the invention.

1. A Slit valve module, comprising:
a plate including magnetically attractable material;
a first solenoid valve correspondingly configured above or under the plate, whereby attracting or non-attracting said plate; and
a second solenoid valve correspondingly configured at a side of the plate, whereby attracting or non-attracting the plate;
wherein the plate is embedded in the wall of a process chamber.

2. The module according to claim 1, wherein the magnetically attractable material comprises a first magnetic element configured in the plate corresponding to said first solenoid valve to facilitate being attracted by the first solenoid valve.

3. The module according to claim 1, wherein the magnetic material comprises a second magnetic element configured at lateral side of the plate corresponding to said second solenoid valve to facilitate being attracted or repulsed by the second solenoid valve.

4. The module according to claim 1, wherein the plate contains at least one slot.

5. The module according to claim 1, wherein the plate is a block without a slot.

6. The module according to claim 1, wherein the plate has one or more inner cavities or is made of porous materials.

7. A slit valve module comprising:
a plate including magnetic material;
a first solenoid valve configured correspondingly above or under said plate, whereby attracting/non-attracting or repulsing/non-repulsing the said plate; and
a second solenoid valve configured correspondingly aside the plate, whereby attracting/non-attracting or repulsing/non-repulsing the said plate;
wherein the said plate is embedded in the wall of a process chamber.

8. The module according to claim 7, wherein the magnetic material comprises a first magnetic element configured in said plate corresponding to aid first solenoid valve to facilitate being attracted or repulsed by said first solenoid valve.

9. The module according to claim 7, wherein the magnetic material comprises a second magnetic element configured at a lateral side of the plate corresponding to said second solenoid valve to facilitate being attracted or repulsed by said second solenoid valve.

10. The module according to claim 7, wherein the plate contains at least one slot.

11. The module according to claim 7, wherein the plate is a block without a slot.

12. The module according to claim 7, wherein the plate has one or more cavities or is made of porous materials

13. A method of closing or opening a slit valve, comprising steps of:
providing a pulse to a first solenoid valve by a power source, whereby pushing a plate vertically; and
providing a pulse to a second solenoid valve by a power source, whereby attracting or repulsing said plate to seal or unseal a chamber.

14. The method according to claim 13, further comprising a step of moving the plate to open or close the valve by using natural gravity.

15. The method according to claim 13, further comprising sealing or unsealing the channel by the plate through existing pressure difference generated by the vacuum applied in the chamber.

16. A semiconductor apparatus having a slit valve module as in claim 1, which comprises:
a process chamber;
wherein the slit valve module is embedded in the process chamber.

17. A semiconductor apparatus having a slit valve module as in claim 7, which comprises:
a process chamber;
wherein the slit valve module is embedded in the process chamber.
